(19) United States
(12) Patent Application Publication
(10) Pub. No.: US 2024/0372055 A1
(43) Pub. Date: Nov. 7, 2024

(54) DISPLAY DEVICE AND METHOD FOR MANUFACTURING DISPLAY DEVICE

(71) Applicant: Japan Display Inc., Tokyo (JP)

(72) Inventors: Yoichi KAMIJO, Tokyo (JP); Yoshikatsu IMAZEKI, Tokyo (JP); Koichi MIYASAKA, Tokyo (JP); Shuichi OSAWA, Tokyo (JP); Yoshifumi KAMEI, Tokyo (JP)

(73) Assignee: Japan Display Inc., Tokyo (JP)

(21) Appl. No.: 18/773,929

(22) Filed: Jul. 16, 2024

Related U.S. Application Data
(63) Continuation of application No. PCT/JP2022/046703, filed on Dec. 19, 2022.

(30) Foreign Application Priority Data
Jan. 18, 2022 (JP) 2022-005714

(51) Int. Cl. H01L 33/62; H01L 25/075; H01L 33/00; H01L 33/60

(52) U.S. Cl. CPC H01L 33/62; H01L 25/0753; H01L 33/005; H01L 33/60; H01L 2933/0058; H01L 2933/0066

(57) ABSTRACT

A display device includes a substrate having a first surface and a second surface opposite the first surface, a first chip arranged on the first surface and having a first terminal forming surface on which a first terminal is arranged on an opposite side to a first mounting surface in contact with the first surface, and a second chip arranged on the first surface, having a second terminal forming surface on which a second terminal is arranged on an opposite side of a second mounting surface in contact with the first surface, and having a different thickness from the first chip, wherein an upper surface of the first terminal and an upper surface of the second terminal are located on a same surface parallel to the second surface.

### CROSS-REFERENCE TO RELATED APPLICATIONS

This application is a Continuation of International Patent Application No. PCT/JP2022/046703, filed on Dec. 19, 2022, which claims the benefit of priority to Japanese Patent Application No. 2022-005714, filed on Jan. 18, 2022, the entire contents of which are incorporated herein by reference.

### FIELD

An embodiment of the present invention relates to a display device and a method for manufacturing the display device. In particular, the present invention relates to a method for manufacturing a display device with a mounted LED (Light Emitting Diode) chip.

### BACKGROUND

In recent years, as a next-generation display device, an LED display in which micro LED chips are mounted on respective pixels has been developed. The LED display has a configuration in which a plurality of LED chips and a plurality of circuit chips are mounted on a substrate. The circuit chips have driving circuits for causing LEDs to emit light. These driving circuits are electrically connected to the respective LED chips.

The circuit chip and the LED chip described above are electrically connected to each other via a connecting electrode of a wiring layer. Specifically, terminals arranged above the LED chip and the circuit chip are electrically connected to a plurality of connecting electrodes arranged above the wiring layer. For example, U.S. Pat. No. 10,937,815 discloses a configuration in which a LED chip is arranged on a recess of an organic film corresponding to a thickness (or total height) of each of the LED chips.

### SUMMARY

A display device according to an embodiment of the present invention includes a substrate having a first surface and a second surface opposite the first surface, a first chip arranged on the first surface and having a first terminal forming surface on which a first terminal is arranged on an opposite side of a first mounting surface in contact with the first surface, and a second chip arranged on the first surface, having a second terminal forming surface on which a second terminal is arranged on an opposite side of a second mounting surface in contact with the first surface, and having a different thickness from the first chip, wherein an upper surface of the first terminal and an upper surface of the second terminal are located on the same surface parallel to the second surface.

A method for manufacturing a display device according to an embodiment of the present invention includes forming a first recess and a second recess having a different depth from the first recess on a first surface of a substrate, mounting a first chip having a first terminal on the first recess, mounting a second chip having a second terminal and having a different thickness from the first chip on the second recess, forming an insulating layer above the first chip and the second chip, the insulating layer having a surface including an upper surface of the first terminal and an upper surface of the second terminal parallel to the second surface opposite to the first surface, and forming a wiring connecting the first terminal and the second terminal on the surface.

A method for manufacturing a display device according to another embodiment of the present invention includes forming a first protrusion and a second protrusion having a different height from the first protrusion on a first surface of a substrate, mounting a first chip having a first terminal on the first protrusion, mounting a second chip having a second terminal and having a different thickness from the first chip on the second protrusion, forming an insulating layer above the first chip and the second chip, the insulating layer having a surface including an upper surface of the first terminal and an upper surface of the second terminal parallel to the second surface opposite to the first surface, and forming a wiring connecting the first terminal and the second terminal on the surface.

### BRIEF DESCRIPTION OF DRAWINGS

FIG. 1 is a schematic diagram of a display device according to an embodiment of the present invention.

FIG. 2 is an enlarged view of a pixel in a display device according to an embodiment of the present invention.

FIG. 3 is a cross-sectional view of a pixel in a display device according to an embodiment of the present invention.

FIG. 4 is a cross-sectional view showing a method for manufacturing a display device according to an embodiment of the present invention.

FIG. 5 is a cross-sectional view showing a method for manufacturing a display device according to an embodiment of the present invention.

FIG. 6 is a plan view showing a method for manufacturing a display device according to an embodiment of the present invention.

FIG. 7 is a cross-sectional view showing a method for manufacturing a display device according to an embodiment of the present invention.

FIG. 8 is a cross-sectional view showing a method for manufacturing a display device according to an embodiment of the present invention.

FIG. 9 is a cross-sectional view showing a method for manufacturing a display device according to an embodiment of the present invention.

FIG. 10 is a cross-sectional view of a pixel in a display device according to an embodiment of the present invention.

FIG. 11 is a cross-sectional view showing a method for manufacturing a display device according to an embodiment of the present invention.

FIG. 12 is a cross-sectional view showing a method for manufacturing a display device according to an embodiment of the present invention.

FIG. 13 is a cross-sectional view showing a method for manufacturing a display device according to an embodiment of the present invention.

FIG. 14 is a cross-sectional view of a pixel in a display device according to a modification of the present invention.

FIG. 15 is a cross-sectional view of a pixel in a display device according to a modification of the present invention.

FIG. 16 is an enlarged view of pixels in a display device according to a modification of the present invention.

### DESCRIPTION OF EMBODIMENTS

Hereinafter, embodiments of the present invention will be described with reference to the drawings. It should be noted that the embodiments are merely examples, and those that can be easily conceived by a person skilled in the art by appropriately changing them while keeping the gist of the invention are naturally included in the scope of the present invention. Further, in order to make the description clearer, the drawings may be schematically represented with respect to widths, thicknesses, shapes, and the like of the respective portions as compared with actual embodiments. However, the illustrated shapes are merely examples, and do not limit the interpretation of the present invention.

In the embodiments of the present disclosure, a direction from a substrate toward an LED chip is referred to as “upper”, and the opposite direction is referred to as “lower”. However, the expression “above” or “below” merely describes an upper limit relationship of each element. For example, the expression that the LED chip is arranged above the substrate includes cases where another member is interposed between the substrate and the LED chip. Furthermore, the expression “above” or “below” includes not only a case where each element overlaps each other in a plan view, but also a case where each element does not overlap each other.

When describing the embodiments of the present invention, elements having the same functions as those of the elements already described are given the same reference signs or the same reference signs with alphabetical characters or other symbols added, and description thereof may be omitted. In addition, in the case where an element needs to be described separately with respect to the respective colors of RGB, the letters R, G, or B are attached after the sign indicating the element to distinguish the element. However, in the case where the elements do not need to be described separately for the respective colors of RGB, the description will be made using only the reference signs indicating the elements.

An object of the present invention is to align terminals of a plurality of chips having different thicknesses on the same surface.

### First Embodiment

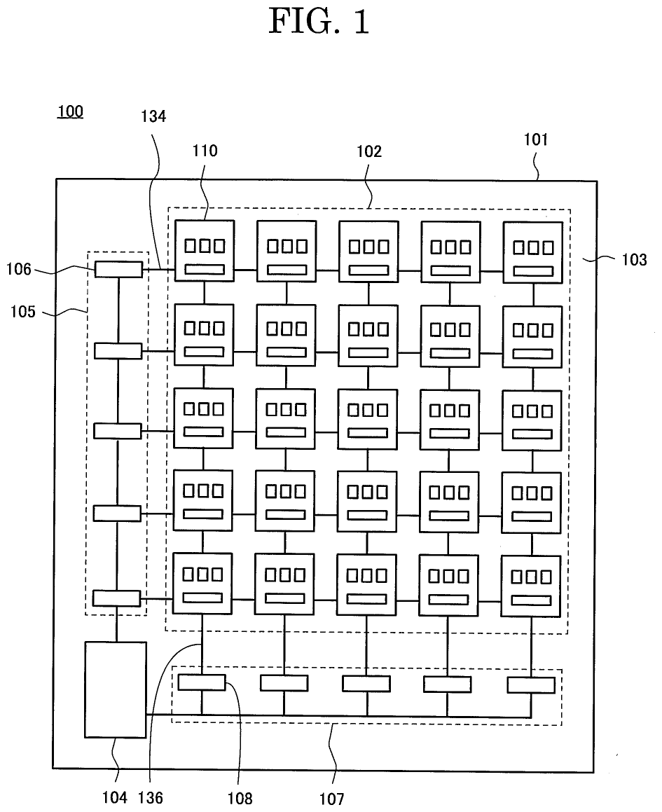

In the present embodiment, a display device 100 according to an embodiment of the present invention will be described with reference to FIG. 1 to FIG. 9.

### [Overview of Display Device]

FIG. 1 is a schematic diagram of the display device 100 according to an embodiment of the present invention. The display device 100 includes a substrate 101 having a display region 102 and a peripheral region 103 surrounding the display region 102. In the display region 102, a plurality of pixels 110 are arranged in an array. The pixels 110 include an LED chip and a circuit chip. In the peripheral region 103, a controller 104, a row control circuit 105, and a column control circuit 107 are arranged. In addition, the row control circuit 105 and the column control circuit 107 are also referred to as driving circuits that drive the pixels 110.

The column control circuit 107 includes a column driver 108 connected to each column of pixels 110. The column driver 108 is connected to a data line 136 that supplies a data signal in common to all the pixels 110 arranged in the column. The row control circuit 105 also includes a row driver 106 connected to each row of pixels 110. The row driver 106 is connected to a select line 134 that supplies a select signal in common to all the pixels 110 arranged in the row. The plurality of pixels 110 in the array form are controlled by the controller 104 via the row control circuit 105 and the column control circuit 107.

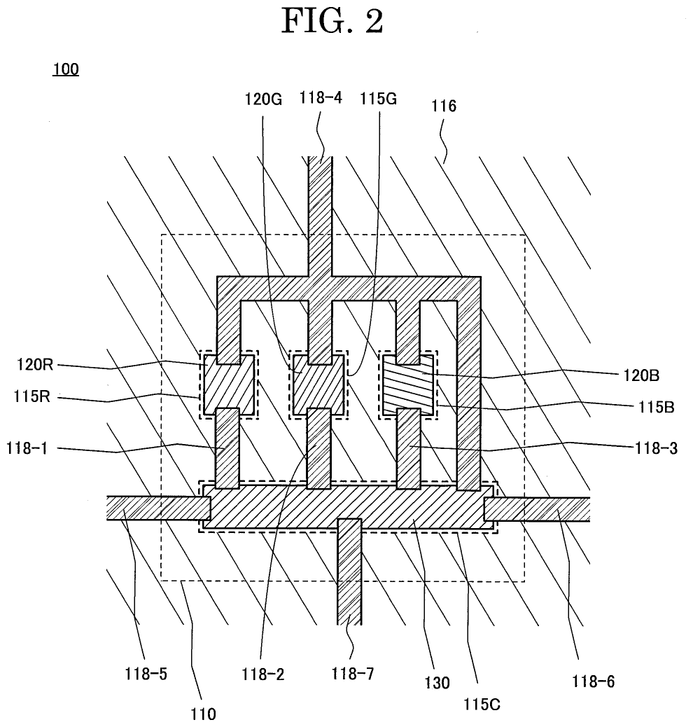

FIG. 2 is an enlarged view of the pixel 110 in the display device 100. The pixel 110 includes a plurality of LED chips 120 and a circuit chip 130. The plurality of LED chips 120 include, for example, red, green, and blue LEDs that emit red, green, and blue lights. By controlling the LED chips 120R, 120G, and 120B, a full-color pixel 110 can be formed.

The circuit chip 130 is formed on a substrate different from the substrate 101. The circuit chip 130 is, for example, a bare chip, such as an unpackaged integrated circuit board, such as a semiconductor substrate.

Although not shown in FIG. 2, the LED chip 120 has two terminals. The two terminals of LED chip 120 are arranged above an upper surface of the LED chip 120 (a terminal forming surface 120u facing away from a mounting surface 120b on the substrate 101). The circuit chip 130 has seven terminals. The seven terminals of the circuit chip 130 are arranged above an upper surface of the circuit chip 130 (a terminal forming surface 130u facing away from a mounting surface 130b on the substrate 101). One terminal of the LED chip 120R is connected to the circuit chip 130 via a wiring 118-1. One terminal of the LED chip 120G is connected to the circuit chip 130 via a wiring 118-2. One terminal of the LED chip 120B is connected to the circuit chip 130 via a wiring 118-3. A wiring 118-4 respectively connects the other terminal of the LED chip 120R, the other terminal of the LED chip 120G, the other terminal of the LED chip 120B, the circuit chip 130, and the circuit chips 130 of the pixels 110 adjacent to each other in a column direction. A wiring 118-5 connects the circuit chip 130 and the circuit chips 130 of the pixels 110 adjacent to each other in a row direction. A wiring 118-6 connects the circuit chip 130 and the circuit chips 130 of the pixels 110 adjacent to each other in the row direction. A wiring 118-7 connects the circuit chip 130 and the LED chips 120R, 120G, 120B, and the circuit chip 130 of the pixels 110 adjacent to each other in the column direction. Here, the wirings 118-5 and 118-6 connecting the pixels 110 adjacent to each other in the row direction function as the select lines 134. The select lines 134 electrically connect the row driver 106 and the circuit chip 130 of the pixel 110 adjacent to each other in the row direction. The wirings 118-4 and 118-7 connecting the pixels 110 adjacent to each other in the column direction function as the data lines 136. The data lines 136 electrically connect the column driver 108 to the LED chips 120 and the circuit chips 130 of the pixels 110 adjacent to each other in the column direction.

In the present embodiment, three LED chips 120 and one circuit chip 130 are arranged in one pixel 110. However, the present invention is not limited thereto, and for example, three LED chips 120 and three circuit chips 130 may be arranged in one pixel 110, and one LED chip 120 and one circuit chip 130 may be arranged in one pixel 110.

### [Configuration of Pixel]

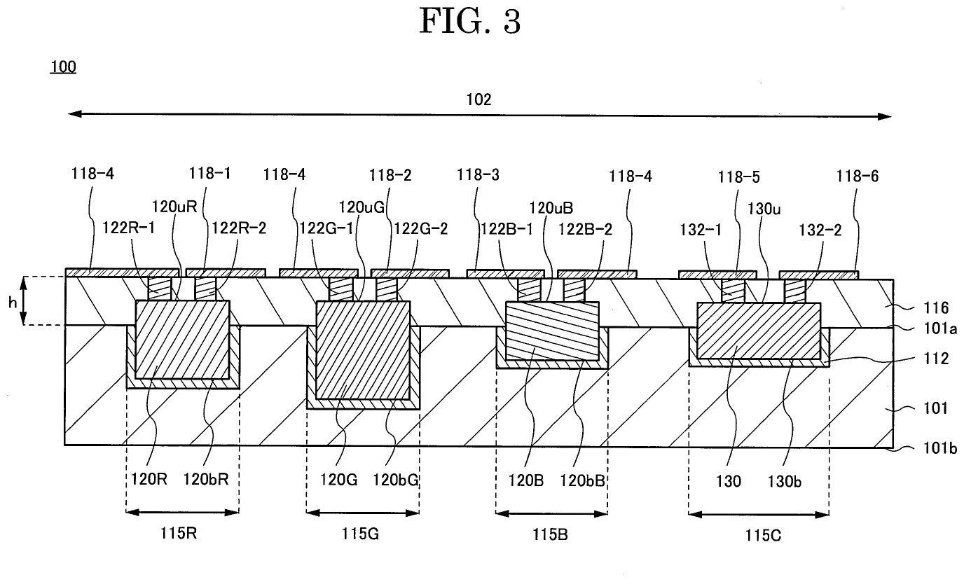

FIG. 3 is a schematic cross-sectional view of the LED chips 120R, 120G, and 120B and the circuit chip 130. Although FIG. 3 corresponds to a cross section of the pixel 110, for ease of explanation, the schematic cross-sectional view shown in FIG. 3 does not correspond to a plan view of the pixel 110 shown in FIG. 2.

A plurality of recesses 115 are provided on one surface 101a of the substrate 101. A plurality of recesses 115R, 115G, 115B, and 115C respectively correspond to positions where the LED chips 120R, 120G, and 120B and the circuit chip 130 are arranged. The LED chip 120R is arranged in the recess 115R, the LED chip 120G is arranged in the recess 115G, the LED chip 120B is arranged in the recess 115B, and the circuit chip 130 is arranged in the recess 115C. For example, a glass substrate or a resin substrate is used as the substrate 101.

A shape of the recess 115 when seen in a plan view is substantially the same as a shape of the corresponding LED chip 120 when seen in a plan view. A depth from the one surface 101a to a bottom surface of the recess 115 depends on a height (thickness) of the corresponding LED chip 120 or the circuit chip 130 from the mounting surfaces 120b or 130b to the substrate 101 to chips (upper surface) of terminals 122 or 132. At least one of the plurality of LED chips 120R, 120G, and 120B and the circuit chip 130 differs in height from the others. Thus, at least one of the plurality of recesses 115 differs in depth from the others. The depth from the surface 101a to the bottom surface of the recess 115 is obtained by subtracting a height h from the surface 101a of the substrate 101 to an upper surface of the terminal from a height of the corresponding LED chip 120 or the circuit chip 130.

The depth of the recess 115 is less than the height of the corresponding LED chip 120. That is, the terminals 122 of the LED chips 120 and the terminals 132 of the circuit chip 130 protrude from the surface 101a of the substrate 101. In FIG. 3, not only the terminals 122 and 132 but also a part of the main bodies of the LED chip 120 and the circuit chip 130 protrude from the surface 101a of the substrate 101. However, the present invention is not limited thereto, and at least a part of the terminals 122 of the LED chips 120 and the terminals 132 of the circuit chip 130 may protrude from the surface 101a of the substrate 101.

The plurality of recesses 115 are spaced apart from each other. However, the present invention is not limited thereto, and as long as the condition described above is satisfied, the recess 115 may be continuous, or may be one recess 115 having unevenness on the bottom surface.

A distance (height) from the surface 101a (or a surface 101b opposed to the surface 101a) of the LED chip 120 to upper surfaces of the terminals 122 of the LED chips 120 and a distance (height) from the surface 101a (or a surface 101b opposed to the surface 101a) of the circuit chip 130 to an upper surface of the terminal 132 of the circuit chip 130 are substantially the same. Therefore, the upper surfaces of the terminals 122 of the LED chips 120 and the upper surface of the terminal 132 of the circuit chip 130 are located on the same plane. A surface on which the upper surfaces of the terminals 122 of the LED chips 120 and the upper surface of the terminal 132 of the circuit chip 130 are located is substantially parallel to the surface 101b of the substrate 101 which is opposed to the surface 101a on which the recess 115 is arranged. A lower surface of the recess 115 on which the LED chip 120 and the circuit chip 130 are arranged is substantially parallel to the surface 101b of the substrate 101. Here, “substantially parallel” includes an error of +1° from a plane parallel to the plane 101b of the substrate 101. The surface on which the upper surfaces of the terminals 122 of the LED chips 120 and the upper surface of the terminal 132 of the circuit chip 130 are located on the surface 101a of the substrate 101.

A micro LED or a mini LED is used as the LED chip 120. The micro LED is a LED having a size of 100 μm or less, and the mini LED is a LED having a size of 100 μm to 200 μm. In the display device 100, any size of LED can be used, and may be appropriately used depending on a size of the pixel 110. In the present embodiment, the LED chip 120 is a micro LED, and has, for example, a vertical width of 7 μm to 150 μm, a horizontal width of 3 μm to 100 μm, and a height of about 3 μm to 15 μm. The LED chip 120 is arranged such that terminals 122-1 and 122-2 are provided on an upper side. The terminals 122-1 and 122-2 are formed of, for example, a conductive material such as gold (Au), copper (Cu), silver (Ag), tin (Sn), or aluminum (AI). The same applies to the LED chips 120G and 120B and the circuit chip 130. The LED chip 120 emits light toward the substrate 101. Therefore, the substrate 101 side serves as a display surface of the display device 100.

An adhesive layer 112 is provided between the recesses 115 and the LED chips 120 and between the recess 115 and the circuit chip 130. The adhesive layer 112 covers a bottom surface and an inner surface of the recess 115. The adhesive layer 112 fixes the LED chips 120 arranged in the recesses 115 of the substrate 101. Therefore, the adhesive layer 112 may be arranged at least on the bottom surface of the recess 115. In this case, an insulating layer 116, which will be described later, may be arranged above the inner surface of the recess 115. On the other hand, the adhesive layer 112 may be continuously arranged above the surface 101a of the substrate 101 from the bottom surface and the inner surface of the recessed portion 115.

An adhesive layer having a sufficient light-transmitting property in a visible-light region such as a VPA adhesive layer, a polyimide-based adhesive layer, an acrylic-based adhesive layer, a silicone-based adhesive layer, a polyester-based adhesive layer, or a rubber-based adhesive layer is used as the adhesive layer 112. The adhesive layer 112 may be a photosensitive resin. A thickness of the adhesive layer 112 is, for example, 1 μm or more and 5 μm or less. If the thickness is small, adhesive strength becomes weak, and if the thickness is large, cost increases, and moreover, an adhesive stain caused by the adhesive layer tends to occur.

The insulating layer 116 is provided to cover the substrate 101, the LED chips 120R, 120G, and 120B, and the circuit chip 130. The insulating layer 116 embeds the LED chip 120R, 120G, and 120B and the circuit chip 130 on the substrate 101. As the insulating layer 116, for example, an organic resin material such as acrylic, polyimide, polyamide, or epoxy may be used. In addition, as the insulating layer 116, for example, an inorganic material such as silicon oxide or silicon nitride may be used. The insulating layer 116 may be, for example, SOG (Spin on Glass). Further, as the insulating layer 116, a film of an inorganic material and a film of an organic resin material may be used in combination. In the case where an organic resin material is used as the insulating layer 116, the organic resin material functions as a planarization film, and surface unevenness caused by the LED chips 120R, 120G, and 120B and the circuit chip 130 can be relieved. In the case where the insulating layer 116 is made of a transparent inorganic material, although transmittance is low, TFT elements can be formed by increasing heat resistance temperature. The two terminals 122-1 and 122-2 of the LED chip 120 and terminals 132-1 and 132-2 of the circuit chip 130 are exposed on an upper surface of the insulating layer 116.

As shown in FIG. 3, the plurality of wirings 118-1 to 118-6 are provided on the insulating layer 116. The plurality of wirings 118-1 to 118-6 are arranged above a surface where the two terminals 122-1 and 122-2 of the LED chips 120 and the terminals 132-1 and 132-2 of the circuit chip 130 are exposed. As described in FIG. 2, the wirings 118 connect the LED chips 120 and the circuit chip 130. The wirings 118 supply signals for controlling light emission to each of the LED chips 120R, 120G, and 120B. As the wiring 118, for example, a metal such as aluminum or copper is used.

In the display device 100 according to an embodiment of the present disclosure, the substrate 101 has the recesses 115 having different depths corresponding to the LED chip 120 and the circuit chip 130 having different heights, so that the upper surfaces of the terminals 122 of the LED chips 120 and the upper surface of the terminal 132 of the circuit chip 130 can be aligned on the same plane. With this configuration, the wirings 118 can be directly connected to the terminals 122 of LED chips 120 and the terminals 132 of the circuit chip 130, and thus a manufacturing process can be simplified.

### [Method for Manufacturing Display Device]

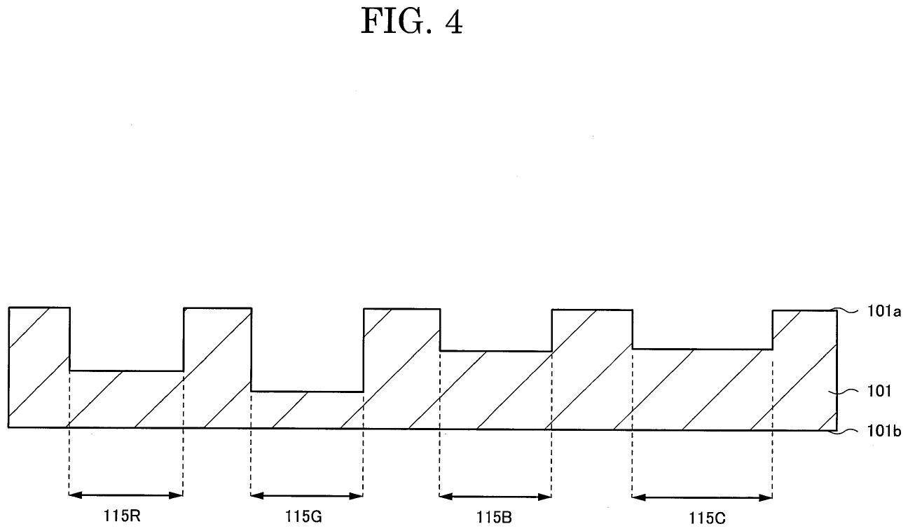

Next, a method for manufacturing the display device 100 according to an embodiment of the present invention will be described with reference to FIG. 4 to FIG. 9.

FIG. 4 is a diagram for explaining a process of forming the plurality of recesses 115R, 115G, 115B, and 115C on the surface 101a of the substrate 101. The plurality of recesses 115R, 115G, 115B, and 115C are etched according to the shapes of the corresponding LED chips 120R, 120G, and 120B and the circuit chip 130. For example, in the case where the substrate 101 is glass, glass etching is performed by using hydrofluoric acid. The plurality of recesses 115R, 115G, 115B, and 115C are different to each other in depth. Preferably, the plurality of recesses 115R, 115G, 115B, and 115C are slightly larger than the shapes of the corresponding LED chips 120R, 120G, and 120B and circuit chips 130. For example, the shape of the recess 115R in a plan view is preferably 1.1 times to 1.5 times the shape of LED chip 120R in a plan view. Etching may be performed several times according to the depth of the recess 115. For example, the recesses 115C and 115B having a shallow depth, the recess 115R, and the recess 115G having a deep depth may be etched in this order by resist-forming/removing each time.

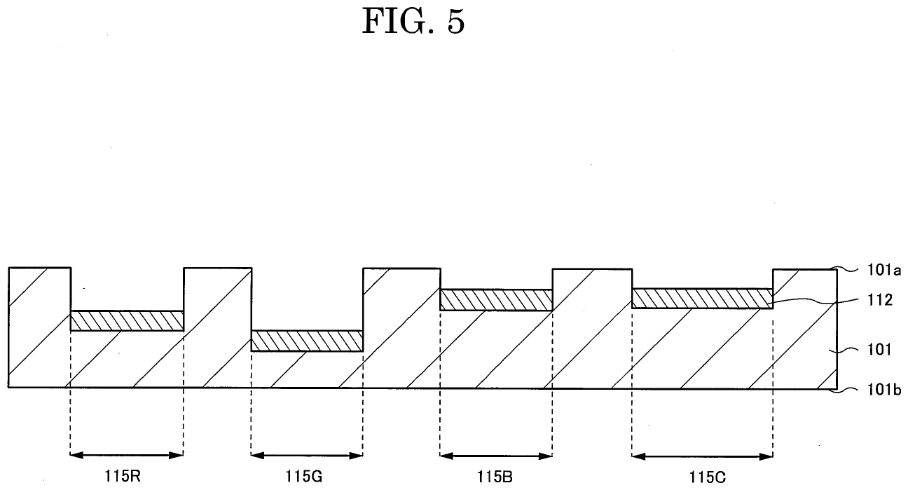

FIG. 5 is a diagram showing a process of forming the adhesive layer 112 on the plurality of recesses 115R, 115G, 115B, and 115C. The adhesive layer 112 may be applied by dropping the adhesive on the bottom surfaces of the plurality of recesses 115R, 115G, 115B, and 115C by an ink jet method or the like. In the case where the adhesive layer 112 is applied to the entire surface 101a of the substrate 101, for example, application methods such as spin-coating, slit-coating, ink-jet coating, and roll-coating may be used. In the case where the adhesive layer 112 is applied to the entire surface 101a of the substrate 101, it may be patterned by photolithography.

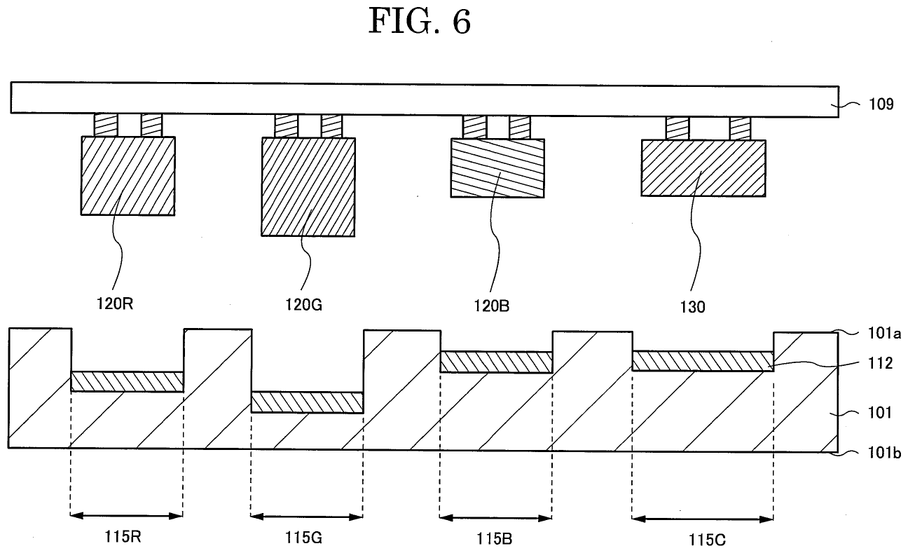

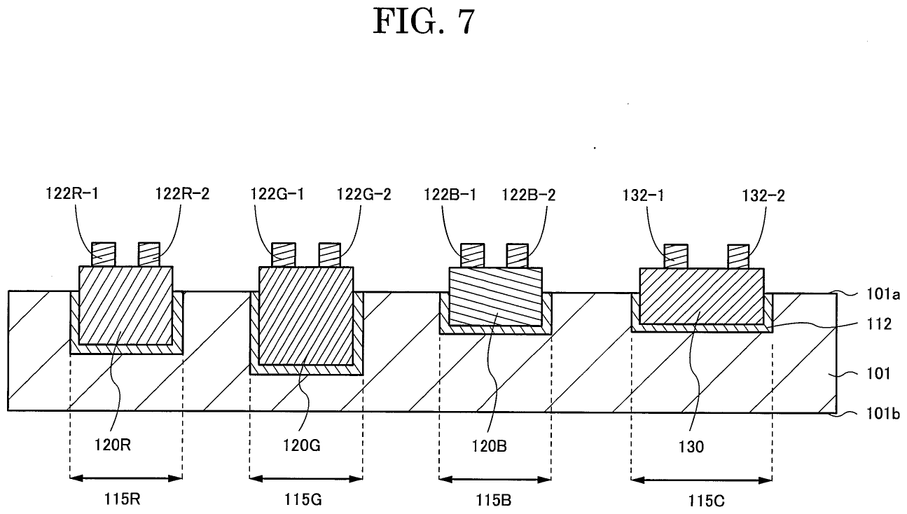

FIG. 6 and FIG. 7 are diagrams for explaining a process of mounting the LED chip 120R, the LED chip 120G, the LED chip 120B and the circuit chip 130 on the plurality of recessed portions 115R, 115G, 115B, 115C of the substrate 101. In the present embodiment, the adhesive layer 112 is selectively provided at the bottom of the plurality of recesses 115. Each of the LED chips 120 and the circuit chip 130 is transferred to a carrier substrate from a LED wafer having a plurality of LEDs formed thereon or a circuit wafer having a plurality of circuit chips formed thereon. The LED chip 120R, the LED chip 120G, the LED chip 120B and the circuit chip 130 on the carrier substrate are picked up from the terminals 122 and 132 side using a transfer substrate 109, and the LED chip 120R, the LED chip 120G, the LED chip 120B and the circuit chip 130 are pushed into the corresponding recesses 115R, 115G, 115B, and 115C and fixed. The adhesive layer 112 arranged above the bottom surface of the recesses 115R, 115G, 115B, and 115C moves to the inner surfaces of the recesses 115R, 115G, 115B, and 115C by pushing the LED chips 120R, 120G, and 120B and the circuit chip 130 into the recesses 115R, 115G, 115B, and 115C.

As described above, by mounting the corresponding LED chip 120R, LED chip 120G, LED chip 120B and the circuit chip 130 on the recesses 115R, 115G, 115B, and 115C of the substrate 101, it is possible to eliminate a difference in height between the LED chip 120R, the LED chip 120G, the LED chip 120B and the circuit chip 130. Therefore, even if the LED chip 120R, the LED chip 120G, the LED chip 120B and the circuit chip 130 having differing heights are mounted at the same time, it is possible to suppress interference with each other. Further, the terminals 122 and 132 of the LED chip 120R, the LED chip 120G, the LED chip 120B and the circuit chip 130 can be aligned with the same position (height), and subsequent manufacturing steps can be simplified. However, the present invention is not limited thereto, and the LED chip 120R, the LED chip 120G, the LED chip 120B and the circuit chip 130 may be mounted several times according to the height of the respective LED chips 120R, 120G, and 120B and the circuit chip 130.

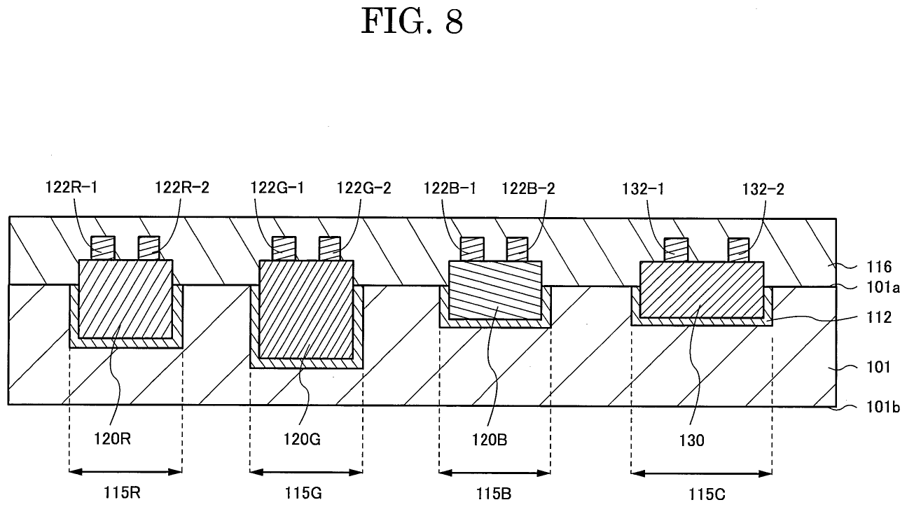

FIG. 8 is a diagram for explaining a process of forming the insulating layer 116 on the LED chips 120 and the circuit chip 130. The insulating layer 116 is formed on the entire surface 101a of the substrate 101. The thickness of the insulating layer 116 may be any thickness as long as it covers the entire terminals 122 and 132 of the LED chip 120R, the LED chip 120G, the LED chip 120B and the circuit chip 130, for example, 2 μm or more and 10 μm or less.

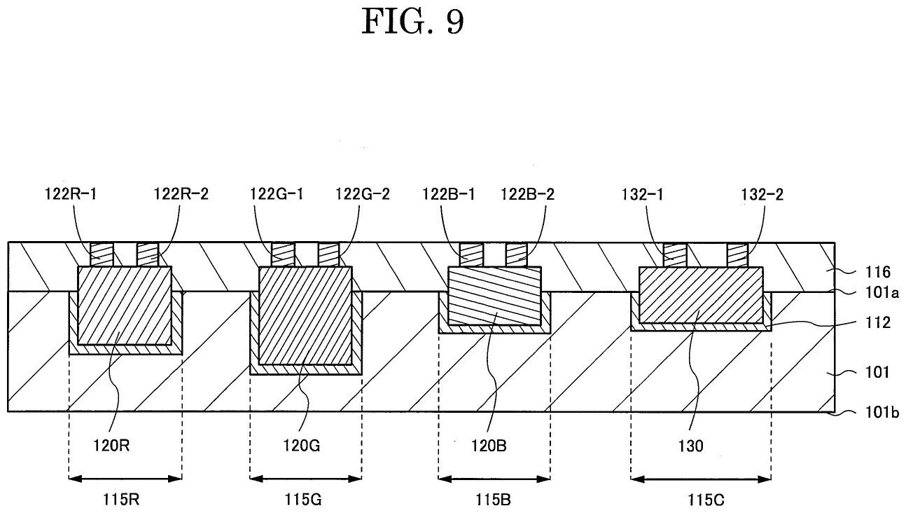

FIG. 9 is a diagram showing a process of patterning the insulating layer 116. For example, the insulating layer 116 is patterned by photolithography to expose the terminals 122 of the LED chip 120 and the terminals 132 of the circuit chip 130 on the same surface. The method in which the terminals 122 of the LED chips 120 and the terminals 132 of the circuit chip 130 are exposed on the same surface is not limited thereto, and may be, for example, half-etching or chemical mechanical polishing.

Finally, the plurality of wirings 118 are formed on the insulating layer 116. The plurality of wirings 118 are formed on a surface where the two terminals 122-1 and 122-2 of the LED chip 120 and the terminals 132-1 and 132-2 of the circuit chip 130 are exposed. The plurality of wirings 118 are formed by forming a conductive film on the insulating layer 116 and appropriately patterning the conductive film. Accordingly, the LED chip 120 and the circuit chip 130 can be connected to each other.

Through the above steps, the display device 100 according to an embodiment of the present invention can be manufactured.

In the manufacturing method of the display device 100 according to an embodiment of the present disclosure, by forming the recesses 115 corresponding to the heights of the corresponding LED chips 120 and the circuit chips 130 in the substrate 101 and mounting the corresponding LED chips 120 and the circuit chips 130, it is possible to eliminate the difference in the heights of the LED chips 120 and the circuit chip 130. As a result, the terminals 122 and 132 of the LED chips 120 and the circuit chip 130 can be aligned with the same position (height), and the manufacturing process can be simplified. Further, the recesses 115 can also be used as a protective substrate (cover glass) that protects a main light emitting surface (mounting surfaces 120b and 130b) of the LED chips 120 and the circuit chip 130 from external impacts or the like by forming it directly on the substrate 101, for example, a hard glass substrate, or the like. Therefore, compared to the conventional method of attaching the protective substrate (cover glass) to the display device, it is possible to contribute to making the display device thinner.

### Second Embodiment

In the first embodiment, although the difference between the heights of the LED chips 120 and the circuit chips 130 is eliminated by the recesses 115 of the substrate 101 corresponding to the LED chips 120 and the circuit chips 130, the present embodiment is not limited thereto. In the second embodiment, the difference in the heights of the LED chips 120 and the circuit chips 130 is eliminated by protrusions 140 on the substrate 101 corresponding to the LED chips 120 and the circuit chip 130. The configuration of a display device 100A according to the present embodiment is the same as the configuration of the display device 100 according to the first embodiment except that the protrusions 140 corresponding to the LED chip 120 and the circuit chip 130 are provided. Descriptions that are the same as those in the first embodiment will be omitted, and parts that are different from the configuration of the display device according to the first embodiment will be described here.

### [Configuration of Pixels]

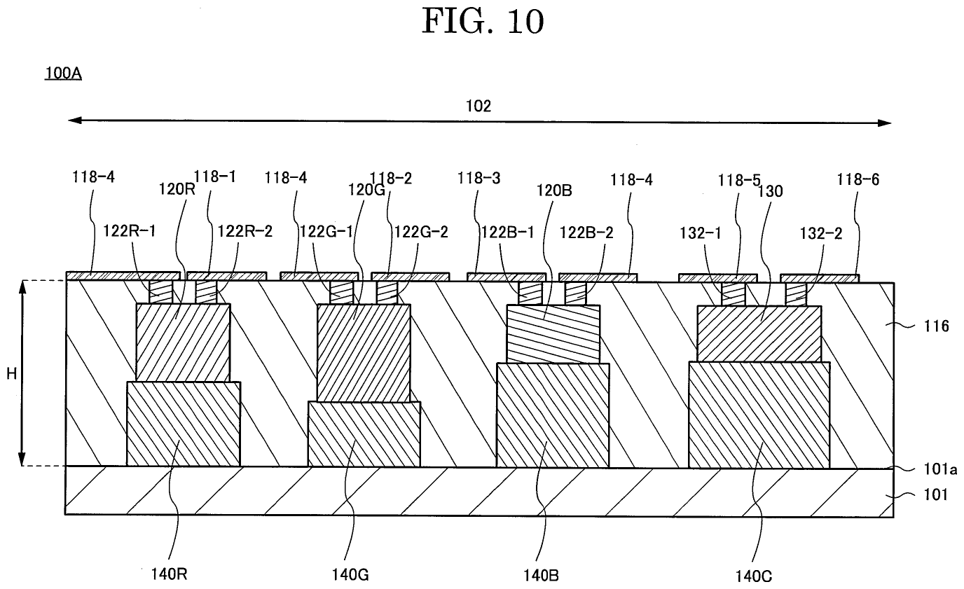

FIG. 10 is a cross-sectional view of the pixel 110 in the display device 100A according to an embodiment. Although FIG. 10 corresponds to a cross section of the pixel 110, for ease of explanation, the schematic cross-sectional view shown in FIG. 10 does not correspond to the plan view of the pixel 110 shown in FIG. 2.

On the surface 101a of the substrate 101, a plurality of protrusions 140 protruding from the surface 101a are provided. Each of a plurality of protrusions 140R, 140G, 140B, and 140C corresponds to positions where the LED chips 120R, 120G, and 120B and the circuit chip 130 are arranged. On the protrusion 140R, the LED chip 120R is arranged, on the protrusion 140G, the LED chip 120G is arranged, on the protrusion 140B, the LED chip 120B is arranged, and on the protrusion 120G, the circuit chip 130 is arranged. The protrusion 140 is preferably a photoresist having an adhesive property, and an adhesive layer having a sufficient light-transmitting property in a visible-light region such as a VPA adhesive layer, a polyimide-based adhesive layer, an acrylic-based adhesive layer, a silicone-based adhesive layer, a polyester-based adhesive layer, or a rubber-based adhesive layer is preferably used. In the present embodiment, the substrate 101 and the plurality of protrusions 140 are formed separately. However, the present invention is not limited thereto, and the substrate 101 and the plurality of protrusions 140 may be integrally formed. Here, the plurality of protrusions 140R, 140G, 140B, and 140C may be formed on the surface 101a of the substrate 101 by etching. For example, the adhesive layer 112 described in the first embodiment may be arranged above upper surfaces of the plurality of protrusions 140.

A shape of the protrusion 140 when seen in a plan view is substantially the same as the shape of the corresponding LED chip 120 when seen in a plan view. A height from the surface 101a to the upper surface of the protrusion 140 depends on a height (thickness) from the mounting surfaces 120b and 130b of the corresponding LED chip 120 or the circuit chip 130 on the substrate 101 to the upper surfaces of the terminals 122 and 132. At least one of the plurality of LED chips 120R, 120G, and 120B and the circuit chip 130 differs in height from the others. Thus, at least one of the plurality of protrusions 140 is different in height from the others. The height from the surface 101a to the upper surface of the protrusion 140 is obtained by subtracting the height of the corresponding LED chips 120 or the circuit chip 130 from a height H from the surface 101a of the substrate 101 to the upper surfaces of the terminals.

The plurality of protrusions 140 are spaced apart from each other. However, the present invention is not limited thereto, and as long as the above condition is satisfied, the protrusion 140 may be continuous or may be one protrusion 140 having unevenness on the upper surface.

A distance (height) between the surface 101a (or the surface 101b opposed to the surface 101a) of the plurality of LED chips 120 and the upper surface of the terminals 122 of the LED chips 120 is substantially the same as a distance between the surface 101a (or the surface 101b opposed to the surface 101a) of the circuit chip 130 and the upper surface of the terminal 132 of the circuit chip 130. Therefore, the upper surfaces of the terminals 122 of the LED chips 120 and the upper surface of the terminal 132 of the circuit chip 130 are located on the same plane. A surface on which the upper surfaces of the terminals 122 of the LED chips 120 and the upper surface of the terminal 132 of the circuit chip 130 are located is substantially parallel to the surface 101b of the substrate 101 facing away from the surface 101a. Here, “substantially parallel” includes an error of +1° from a plane parallel to the surface 101b of the substrate 101. The surface on which the upper surfaces of the terminals 122 of the LED chip 120 and the upper surface of the terminal 132 of the circuit chip 130 are located is located above the surface 101a of the substrate 101.

The insulating layer 116 is provided so as to cover the substrate 101, the protrusions 140, the LED chips 120, and the circuit chip 130. The insulating layer 116 embeds the LED chips 120R, 120G, and 120B and the circuit chip 130 on the substrate 101. The two terminals 122-1 and 122-2 of the LED chip 120 and the terminals 132-1 and 132-2 of the circuit chip 130 are exposed on the upper surface of the insulating layer 116.

As shown in FIG. 10, the plurality of wirings 118-1 to 118-6 are provided on the insulating layer 116. The plurality of wirings 118-1 to 118-6 are arranged above a surface where the two terminals 122-1 and 122-2 of the LED chip 120 and the terminals 132-1 and 132-2 of the circuit chip 130 are exposed. The wiring 118 connects the LED chip 120 and the circuit chip 130.

In the display device 100 according to an embodiment of the present disclosure, the terminals 122 of the LED chips 120 and the upper surfaces of the terminals 132 of the circuit chip 130 can be aligned on the same surface by having the protrusions 140 having different heights corresponding to the LED chips 120 and the circuit chip 130 having different heights. With this configuration, the wirings 118 can be directly connected to the terminals 122 of the LED chip 120 and the terminals 132 of the circuit chip 130, and thus the manufacturing process can be simplified.

### [Method for Manufacturing Display Device]

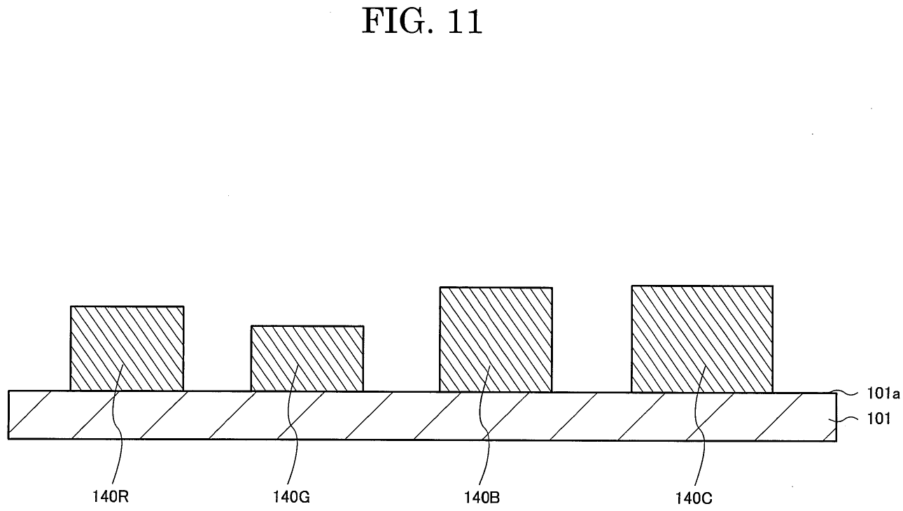

Referring to FIG. 11 to FIG. 13, a manufacturing process of the display device 100A according to an embodiment of the present disclosure will be described. A detailed description of the same steps as those of the first embodiment will be omitted.

FIG. 11 is a diagram for describing a process of forming the plurality of protrusions 140R, 140G, 140B, and 140C on the surface 101a of the substrate 101. The plurality of protrusions 140R, 140G, 140B, and 140C are formed by photolithography according to the shapes of the corresponding LED chips 120R, 120G, and 120B and the circuit chip 130. The plurality of protrusions 140R, 140G, 140B, and 140C differ in height. Preferably, the plurality of protrusions 140R, 140G, 140B, and 140C are slightly larger than the shapes of the corresponding LED chips 120R, 120G, and 120B and circuit chip 130. For example, a shape of the protrusion 140R in a plan view is preferably 1.1 times to 1.5 times the shape of LED chip 120R in a plan view. The photolithography may be performed several times according to the height of the protrusions 140. For example, the high-height protrusions 140C and 140B may be formed by stacking the protrusions a plurality of times. Further, the protrusion 140 may be formed by shaving. In this case, the protrusion 140G having a lower height may be formed by shaving the protrusion a plurality of times.

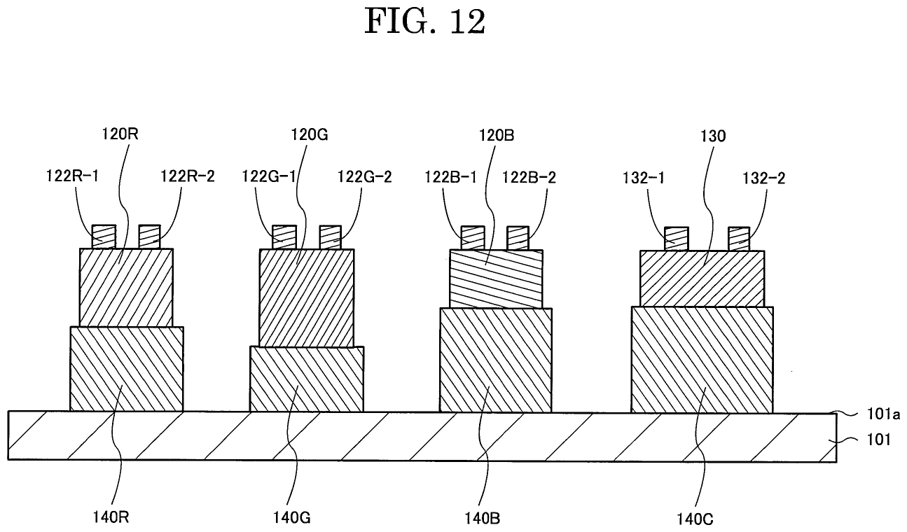

FIG. 12 is a diagram for explaining a step of mounting the LED chip 120R, the LED chip 120G, the LED chip 120B and the circuit chip 130 on the plurality of protrusions 140R, 140G, 140B, and 140C. In the present embodiment, the plurality of protrusions 140 are adhesive. As in the first embodiment, the LED chip 120R, the LED chip 120G, the LED chip 120B and the circuit chip 130 are picked up from the terminals 122 and 132 side using a carrier substrate, and then the LED chip 120R, the LED chip 120G, the LED chip 120B and the circuit chip 130 are crimped to the corresponding protrusions 140R, 140G, 140B, and 140C.

As described above, by mounting the corresponding LED chip 120R, LED chip 120G, LED chip 120B and the circuit chip 130 on the protrusions 140R, 140G, 140B, and 140C of the substrate 101, the difference in height between the LED chip 120R, the LED chip 120G, the LED chip 120B and the circuit chip 130 can be eliminated. Therefore, even if the LED chip 120R, the LED chip 120G, the LED chip 120B and the circuit chip 130 having differing heights are mounted at the same time, it is possible to suppress interference with each other. In addition, the LED chip 120R, the LED chip 120G, the LED chip 120B and the terminals 122 and 132 of the circuit chip 130 can be aligned with the same position (height), and subsequent manufacturing steps can be simplified.

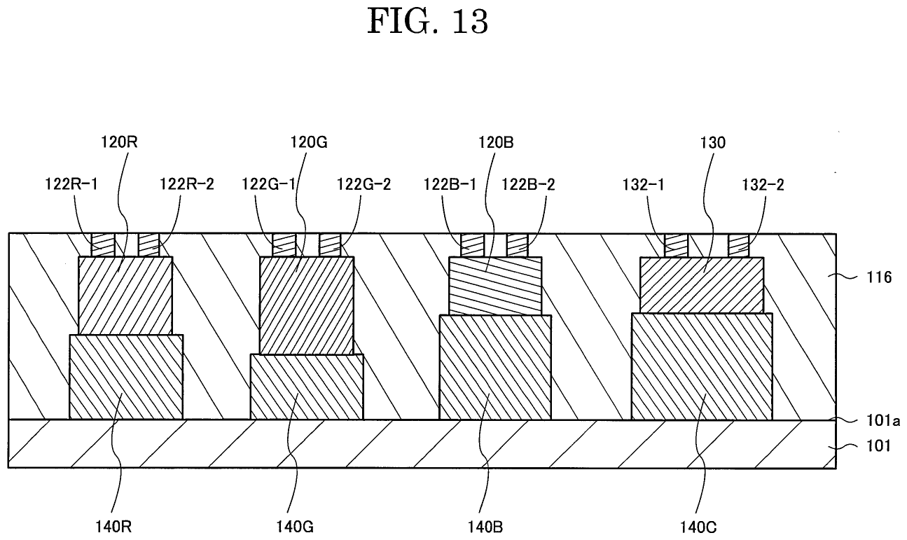

FIG. 13 is a diagram for explaining a process of forming and patterning the insulating layer 116 on the LED chips 120 and the circuit chips 130. The insulating layer 116 is formed on the entire surface 101a of the substrate 101. The thickness of the insulating layer 116 may be any thickness as long as it covers the entire terminals 122 and 132 of the LED chip 120R, the LED chip 120G, the LED chip 120B and the circuit chip 130. Further, the insulating layer 116 is patterned by photolithography to expose the terminals 122 of the LED chips 120 and the terminals 132 of the circuit chip 130. A method in which the terminals 122 of the LED chips 120 and the terminals 132 of the circuit chip 130 are exposed on the same surface is not limited thereto, and may be, for example, half-etching or chemical mechanical polishing.

Finally, the plurality of wirings 118 are formed on the insulating layer 116. The plurality of wirings 118 are formed on a surface where the two terminals 122-1 and 122-2 of the LED chip 120 and the terminals 132-1 and 132-2 of the circuit chip 130 are exposed. The plurality of wirings 118 are formed by forming a conductive film on the insulating layer 116 and appropriately patterning the conductive film. Accordingly, the LED chip 120 and the circuit chip 130 can be connected to each other.

Through the above steps, the display device 100A according to an embodiment of the present disclosure can be manufactured.

In a manufacturing method for the display device 100A according to an embodiment of the present disclosure, a height difference between the LED chips 120 and the circuit chip 130 can be eliminated by forming the protrusions 140 corresponding to the heights of the corresponding LED chips 120 and the circuit chip 130 and mounting the corresponding LED chips 120 and the circuit chip 130 on the corresponding protrusions 140. As a result, the terminals 122 and 132 of the LED chip 120 and the circuit chip 130 can be aligned with the same position (height), and the manufacturing process can be simplified.

### [Modification 1]

In the second embodiment, the LED chips 120 and the circuit chip 130 are embedded in the insulating layer 116. In a modification 1, a light shielding layer 114 is provided between the substrate 101 and the insulating layer 116. A configuration of a display device 100B according to the present modification is the same as the configuration of the display device 100A according to the second embodiment except that the light shielding layer 114 is provided. Descriptions that are the same as those in the second embodiment will be omitted, and parts that are different from the configuration of the display device according to the second embodiment will be described here.

### [Configuration of Pixel]

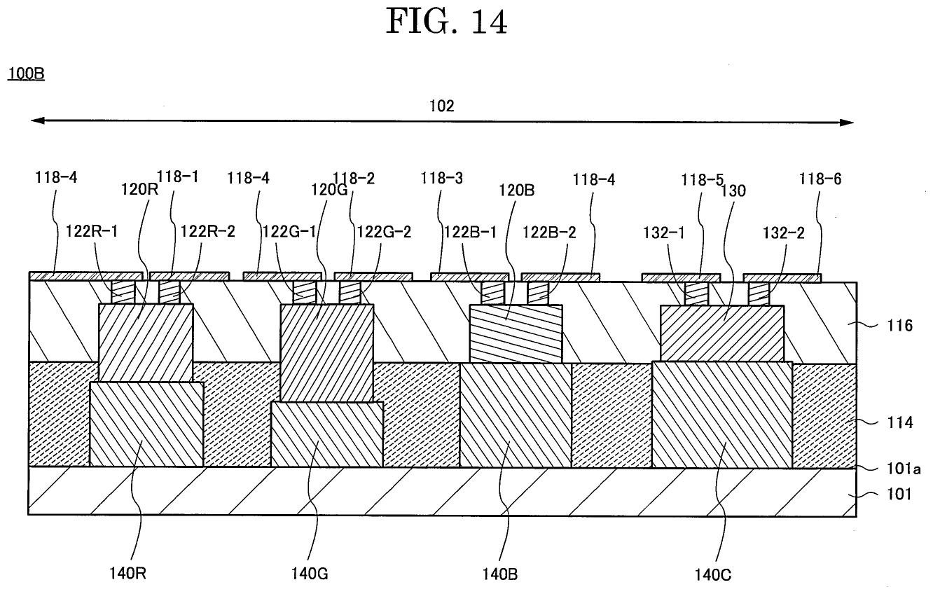

FIG. 14 is a cross-sectional view of the pixel 110 in the display device 100B according to a modification of the present disclosure. Although FIG. 14 corresponds to a cross section of the pixel 110, for ease of explanation, the schematic cross-sectional view shown in FIG. 14 does not correspond to the plan view of the pixel 110 shown in FIG. 2.

The display device 100B according to the modification includes the light shielding layer 114 between the surface 101a of the substrate 101 and a surface where the upper surfaces of the terminals 122 of the LED chips 120 and the upper surface of the terminal 132 of the circuit chip 130 are located. The light shielding layer 114 is arranged between the substrate 101 and the insulating layer 116. The light shielding layer 114 is provided on the substrate 101 so as to surround the protrusions 140, the LED chips 120, and the circuit chip 130. The light shielding layer 114 overlaps the plurality of wirings 118. The light shielding layer 114 is a black film having an insulating property. The light shielding layer 114 is also referred to as a black matrix. A thickness of the light shielding layer 114 is not particularly limited. For example, a black resin material may be used as the light shielding layer 114.

In the display device 100B according to a modification of the present disclosure, the light shielding layer 114 is provided in a region other than a region where the LED chips 120R, 120G, and 120B and the circuit chip 130 is provided. That is, in the display region 102, gaps provided by the LED chips 120, 120G, and 120B, and the circuit chip 130 are filled with the light shielding layer 114. Further, the terminals of the LED chips 120 are provided above. Therefore, the plurality of wirings 118 are routed over the light shielding layer 114. In the display device 100, since the display surface is on a lower side of the substrate 101, the reflected light of the plurality of wirings 118 can be shielded by the light shielding layer 114 in the display region 102. As a result, it is possible to prevent the light emitted from the LED chips 120R, 120G, and 120B from being reflected by the metallic wiring 118 and to provide the display device 100 with improved visibility. Further, it is also possible to suppress light emission from a side of the LED chip 120 toward the light emission surface (101) side, suppress color mixing between different color lights, and increase front brightness.

### [Modification 2]

In the second embodiment, the LED chips 120 and the circuit chip 130 are embedded in the insulating layer 116. In a modification 2, the light shielding layer 114 and a reflective layer 160 are provided between the substrate 101 and the insulating layer 116. A configuration of a display device 100C according to the present modification is the same as the configuration of the display device 100B according to the modification 1 except that the reflective layer 160 is provided. Descriptions that are the same as those in the modification 1 are omitted, and portions that are different from the configuration of the display device according to the modification 1 will be described here.

### [Configuration of Pixel]

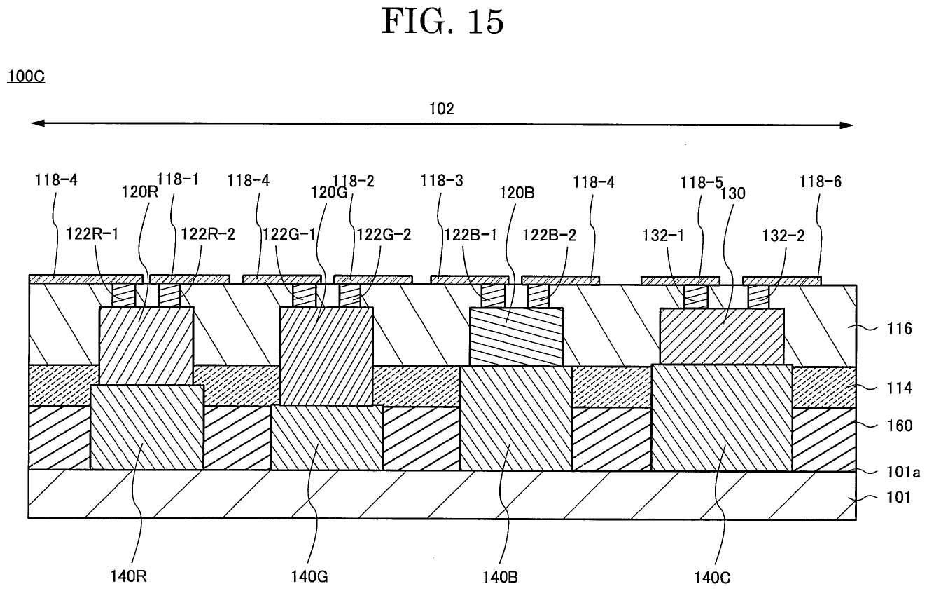

FIG. 15 is a cross-sectional view of the pixel 110 in the display device 100C according to a modification of the present disclosure. Although FIG. 15 corresponds to a cross section of the pixel 110, for ease of explanation, the schematic cross-sectional view shown in FIG. 15 does not correspond to the plan view of the pixel 110 shown in FIG. 2.

The display device 100C according to the modification includes the reflective layer 160 between the substrate 101 and the light shielding layer 114. The reflective layer 160 is provided on the substrate 101 so as to surround the protrusions 140. In the present embodiment, the reflective layer 160 is arranged above the entire surface of the substrate 101 on the surface 101a except for the protrusions 140. However, the present invention is not limited thereto, and the reflective layer 160 may be arranged in a cylindrical shape so as to cover an outer periphery of the plurality of protrusions 140 (a side surface connecting a bottom surface in contact with the substrate 101 and the upper surface on which the LED chips 120 and the circuit chip 130 are mounted), or may be arranged so as to surround the LED chip 120 and the circuit chip 130. The reflective layer 160 may be a transparent resin having a refractive index smaller than a refractive index of the protrusion 140, a white resin that promotes reflection, or a metal film. A thickness of the reflective layer 160 may be any thickness as long as it surrounds a part of the protrusion 140, and is preferably, for example, 0.2 μm or more and 2 μm or less. For example, an aluminum film may be used as the reflective layer 160.

In the display device 100C according to a modification of the present disclosure, the reflective layer 160 is provided so as to surround the protrusion 140. Further, the reflective layer 160 is formed so as to surround a periphery of the protrusions 140. Accordingly, it is possible to provide the display device 100C in which the light emitted from the LED chips 120R, 120G, and 120B is reflected by the reflective layer 160 and provide more efficiently focused light on a front side.

In the display device 100C according to a modification of the present disclosure, the reflective layer 160 is provided so as to surround the protrusions 140. The reflective layer 160 has a refractive index smaller than a refractive index of the protrusion 140. As a result, it is possible to prevent the light emitted from the LED chips 120R, 120G, and 120B from entering the reflective layer 160 and to provide the display device 100C that has more efficiently focused light.

### [Modification 3]

In the first embodiment, the shape of the recess 115 when see in a plan view is substantially the same as the shape of the corresponding LED chip 120 when seen in a plan view. In this modification, the same type of LED chips 120 of adjacent pixels 110 share the recess 115. A configuration of a display device 100D according to the present modification is the same as the configuration of the display device 100 according to the first embodiment except that shapes of the recesses 115 differ. Descriptions that are the same as those in the first embodiment will be omitted, and parts that are different from the configuration of the display device according to the first embodiment will be described here.

### [Overview of Display Device]

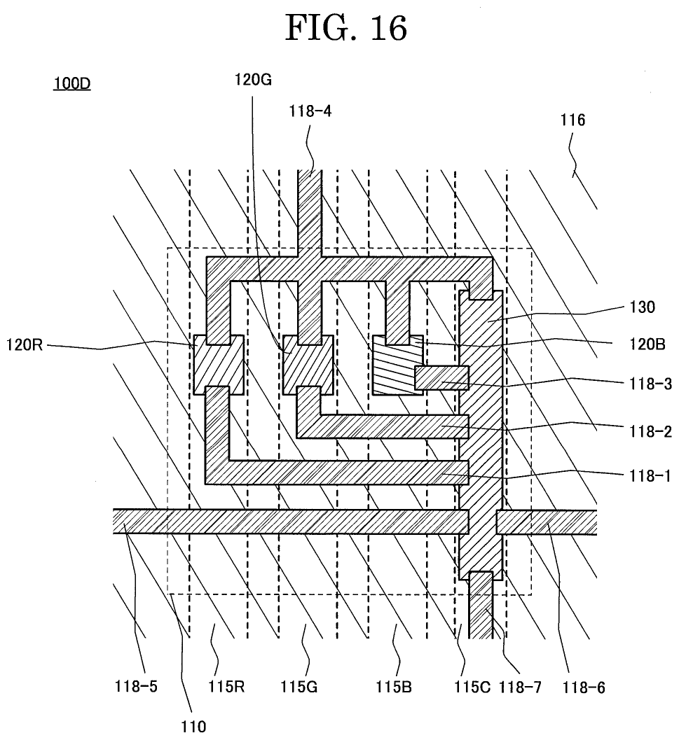

FIG. 16 is an enlarged view of the pixel 110 in the display device 100D. The pixel 110 includes the plurality of LED chips 120 and the circuit chip 130. The plurality of LED chips 120 and the circuit chip 130 are arranged in the corresponding recesses 115.

A shape of the recess 115 when seen in a plan view is a stripe shape. In this variation, the LED chips 120 of the same type of adjacent pixels 110 share the recess 115. The same type of LED chips 120 have the same height. The same type of LED chips 120 of the pixels 110 arranged vertically in FIG. 16 are arranged in the same recess 115. In the recess 115, a gap between the LED chips 120 of adjacent pixels is filled with the insulating layer 116.

In the display device 100D according to a modification of the present disclosure, the LED chips 120 of the same type of adjacent pixels 110 share the recess 115. Thus, the manufacturing process of the display device 100D can be further simplified.

Each of the embodiments described above as the embodiment of the present invention can be appropriately combined as long as they are not mutually contradictory. In addition, a person skilled in the art who appropriately adds, deletes, or changes in design of the constituent elements or adds, omits, or changes in conditions of the steps based on the display device of each embodiment is also included in the scope of the present invention as long as it includes the gist of the present invention.

It is to be understood that the present invention provides other operational effects that are different from the operational effects provided by the aspects of the embodiments described above, and those that are obvious from the description of the present specification or those that can be easily predicted by a person skilled in the art.

What is claimed is:

1. A display device, comprising:
a substrate having a first surface and a second surface opposite the first surface;
a first chip arranged on the first surface and having a first terminal forming surface on which a first terminal is arranged on an opposite side of a first mounting surface in contact with the first surface; and
a second chip arranged on the first surface, having a second terminal forming surface on which a second terminal is arranged on an opposite side of a second mounting surface in contact with the first surface, and having a different thickness from the first chip,
wherein an upper surface of the first terminal and an upper surface of the second terminal are located on the same surface parallel to the second surface.

2. The display device according to claim 1, further comprising a wiring connecting the first terminal and the second terminal and located on the same surface.

3. The display device according to claim 1, wherein
the first surface of the substrate has a first recess on which the first chip is arranged, and a second recess on which the second chip is arranged and having a different depth from the first recess.

4. The display device according to claim 3, wherein the same surface is located above the first surface.

5. The display device according to claim 3, wherein the substrate includes glass.

6. The display device according to claim 1, further comprising:
a first protrusion on which the first chip is arranged and protruding from the substrate; and
a second protrusion on which the second chip is arranged, having a different height to the first protrusion, and protruding from the substrate.

7. The display device according to claim 6, further comprising a light shielding layer arranged between the first surface and the same surface.

8. The display device according to claim 7, further comprising a wiring located on the same surface and connecting the first terminal and the second terminal, wherein
the wiring overlaps the light shielding layer.

9. The display device according to claim 6, wherein the first protrusion and the second protrusion are separated from each other.

10. The display device according to claim 9, further comprising a reflective layer arranged so as to surround the first protrusion and the second protrusion.

11. The display device according to claim 10, wherein refractive indexes of the first protrusion and the second protrusion are larger than a refractive index of the reflective layer.

12. The display device of claim 1, wherein the first chip is selected from a group consisting of an LED chip including an LED that emits red light, an LED chip including an LED that emits green light, an LED chip including an LED that emits blue light, and a circuit chip.

13. The display device of claim 12, wherein the second chip is selected from the group and is different from the first chip.

14. A method for manufacturing a display device, comprising:
forming a first recess and a second recess having a different depth from the first recess on a first surface of a substrate;
mounting a first chip having a first terminal on the first recess;
mounting a second chip having a second terminal and having a different thickness from the first chip on the second recess;
forming an insulating layer above the first chip and the second chip, the insulating layer having a surface including an upper surface of the first terminal and an upper surface of the second terminal parallel to the second surface opposite to the first surface; and
forming a wiring connecting the first terminal and the second terminal on the surface.

15. The method for manufacturing the display device according to claim 14, wherein
the substrate includes glass, and
forming the first recess and the second recess is performed by etching using hydrofluoric acid.

16. A method for manufacturing a display device, comprising:
forming a first protrusion and a second protrusion having a different height from the first protrusion on a first surface of a substrate;
mounting a first chip having a first terminal on the first protrusion;
mounting a second chip having a second terminal and having a different thickness from the first chip on the second protrusion;
forming an insulating layer above the first chip and the second chip, the insulating layer having a surface including an upper surface of the first terminal and an upper surface of the second terminal parallel to the second surface opposite to the first surface; and
forming a wiring connecting the first terminal and the second terminal on the surface.

17. The method for manufacturing the display device according to claim 16, further comprising forming a light shielding layer between the substrate and the insulating layer.

18. The method for manufacturing the display device according to claim 16, further comprising:
forming the first protrusion and the second protrusion so as to be separated from each other; and
forming a reflective layer arranged so as to surround the first protrusion and the second protrusion.

19. The method for manufacturing the display device according to claim 18, wherein
refractive indexes of the first protrusion and the second protrusion are larger than a refractive index of the reflective layer.

20. The method for manufacturing the display device according to claim 14, wherein the first chip and the second chip are different from each other and both are selected from a group consisting of an LED chip including an LED that emits red light, an LED chip including an LED that emits green light, an LED chip including an LED that emits blue light, and a circuit chip.
